(19) United States
(12) Patent Application Publication
(10) Pub. No.: US 2025/0212425 A1
(43) Pub. Date: Jun. 26, 2025

(54) INTEGRATED CIRCUIT DEVICE

(71) Applicant: Samsung Electronics Co., Ltd., Suwon-si (KR)

(72) Inventors: Jungmin PARK, Suwon-si (KR); Beomjong Kim, Suwon-si (KR); Jisung Kim, Suwon-si (KR); Hanjin Lim, Suwon-si (KR); Hyungsuk Jung, Suwon-si (KR)

(73) Assignee: Samsung Electronics Co., Ltd., Suwon-si (KR)

(21) Appl. No.: 18/970,497

(22) Filed: Dec. 5, 2024

(30) Foreign Application Priority Data
Dec. 21, 2023 (KR) 10-2023-0188791

(51) Int. Cl. H10D 1/68; H10B 12/00

(52) U.S. Cl. CPC H10D 1/684; H10B 12/315

(57) ABSTRACT

An integrated circuit device includes a transistor on a substrate, and a capacitor structure connected to the transistor, where the capacitor includes a first electrode, a dielectric layer structure on the first electrode and in which a plurality of dielectric layers are stacked, and a second electrode on the dielectric layer structure, and where the plurality of dielectric layers include a first dielectric layer including a ferroelectric material in a rhombohedral crystal phase, and a second dielectric layer in a crystal phase different from the rhombohedral crystal phase of the first dielectric layer.

### CROSS-REFERENCE TO RELATED APPLICATION

This application is based on and claims priority under 35 U.S.C. § 119 to Korean Patent Application No. 10-2023-0188791, filed on Dec. 21, 2023, in the Korean Intellectual Property Office, the disclosure of which is incorporated by reference herein in its entirety.

### BACKGROUND

Example embodiments of the disclosure relate to an integrated circuit device, and more particularly, to an integrated circuit device including a capacitor structure.

Recently, with the rapid development of miniaturized semiconductor processing technology, the area of the unit cell is decreasing as the high integration of integrated circuit devices is accelerated. Accordingly, the area occupied by capacitors within the unit cell is also decreasing. For example, as the integration level of integrated circuit devices, such as dynamic random-access memory (DRAM), increases, the area of the unit cell decreases, while the required capacitance is maintained or increased. Therefore, a structure that can overcome spatial limitations and design rule limitations in capacitors, improve capacitance, and maintain desired electrical characteristics is needed.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide an integrated circuit device including a dielectric layer structure including a ferroelectric material in a rhombohedral crystal phase.

Additional aspects will be set forth in part in the description which follows and, in part, will be apparent from the description, or may be learned by practice of the presented embodiments.

According to an aspect of an example embodiment, an integrated circuit device may include a transistor on a substrate, and a capacitor structure connected to the transistor, where the capacitor includes a first electrode, a dielectric layer structure on the first electrode and in which a plurality of dielectric layers are stacked, and a second electrode on the dielectric layer structure, and where the plurality of dielectric layers include a first dielectric layer including a ferroelectric material in a rhombohedral crystal phase, and a second dielectric layer in a crystal phase different from the rhombohedral crystal phase of the first dielectric layer.

According to an aspect of an example embodiment, an integrated circuit device may include a transistor on a substrate, and a capacitor structure connected to the transistor, where the capacitor includes a first electrode, a dielectric layer structure on the first electrode, and a second electrode on the dielectric layer structure, where the dielectric layer structure includes a single layer, and the dielectric layer structure includes a first ferroelectric material in a rhombohedral crystal phase.

According to an aspect of an example embodiment, an integrated circuit device may include a transistor on a substrate, and a capacitor structure connected to the transistor, where the capacitor includes a first electrode, a dielectric layer structure on the first electrode and in which a plurality of dielectric layers are stacked, and a second electrode on the dielectric layer structure, and where the plurality of dielectric layers include a first dielectric layer comprising a first ferroelectric material in a rhombohedral crystal phase, a second dielectric layer comprising a second ferroelectric material in an orthorhombic crystal phase, and a third dielectric layer comprising an anti-ferroelectric material in a tetragonal crystal phase.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view of an integrated circuit device according to one or more example embodiments;

FIG. 2A is an enlarged view of portion CX1 in FIG. 1 according to one or more example embodiments;

FIGS. 2B-2D are enlarged views of a portion of an integrated circuit device according to one or more example embodiments;

FIG. 3 is a diagram of an integrated circuit device according to one or more example embodiments;

FIG. 4 is a cross-sectional view taken along line B1-B1′ in FIG. 3 according to one or more example embodiments;

FIG. 5 is an enlarged view of portion CX2 in FIG. 4 according to one or more example embodiments;

FIG. 6 is a diagram of an integrated circuit device according to one or more example embodiments;

FIG. 7 is a cross-sectional view taken along line B2-B2′ in FIG. 6 according to one or more example embodiments;

FIG. 8 is an enlarged view of portion CX3 in FIG. 7 according to one or more example embodiments; and

FIG. 9 is a diagram of a system including an integrated circuit device according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

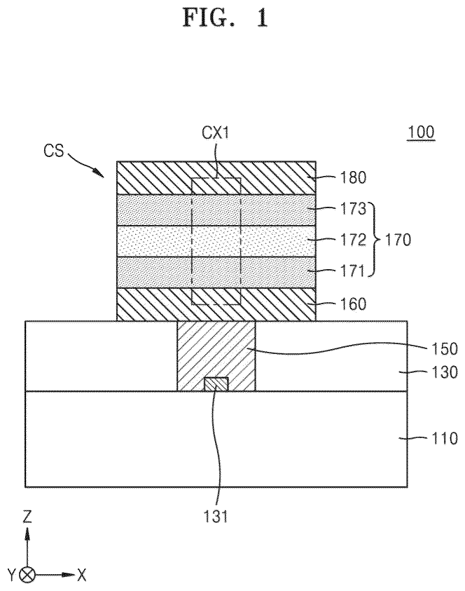

FIG. 1 is a cross-sectional view of an integrated circuit device according to one or more example embodiments.

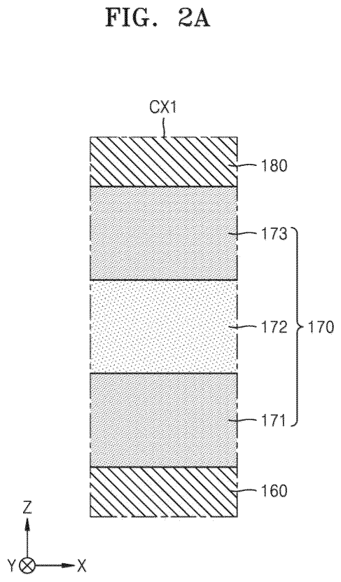

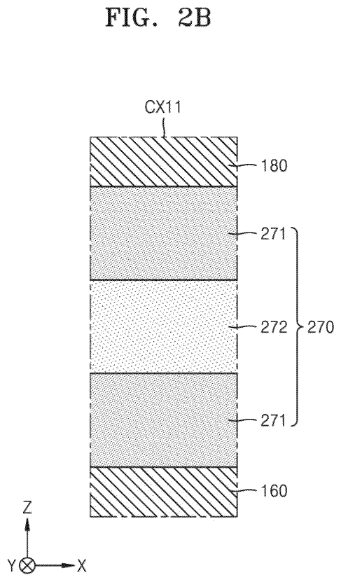

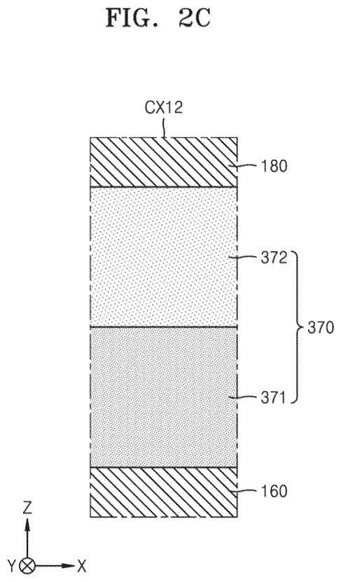

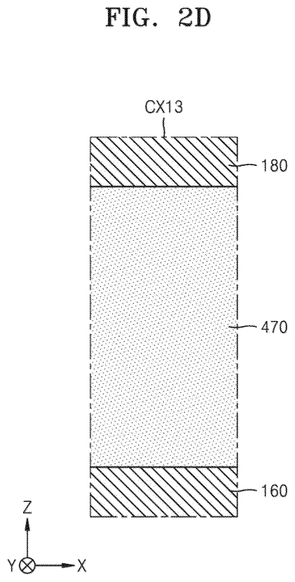

FIG. 2A is an enlarged view of portion CX1 in FIG. 1 according to one or more example embodiments.

Referring to FIGS. 1 and 2A, an integrated circuit device 100 may include a lower insulating layer 130 disposed on a substrate 110, a transistor 131 on the substrate 110, a contact 150 disposed on the substrate 110 and partially covered by the lower insulating layer 130, and a capacitor structure CS disposed on the contact 150, the capacitor structure CS being electrically connected to the transistor 131.

The substrate 110 may include a semiconductor material, such as silicon (Si), germanium (Ge), or silicon germanium (SiGe), silicon carbide (SiC), gallium arsenide (GaAs), indium arsenide (InAs), or indium phosphide (InP). In one or more embodiments, the substrate 110 may include a conductive region (for example, a well doped with impurities), or a structure doped with impurities.

A switching element, such as a transistor 131 and diode, that provides signals to the capacitor structure CS may be provided on the substrate 110. The lower insulating layer 130 may be formed on the substrate 110 and cover the switching element, and the contact 150 may be electrically connected to the switching element.

The capacitor structure CS may include a first electrode 160, a dielectric layer structure 170, and a second electrode 180, which may be sequentially stacked on the contact 150. In one or more embodiments, the dielectric layer structure 170 may be positioned between the first electrode 160 and the second electrode 180, and the first electrode 160 may contact the contact 150. In one or more embodiments, the dielectric layer structure 170 may be positioned between the first electrode 160 and the second electrode 180, and the second electrode 180 may contact the contact 150.

Each of the first electrode 160 and the second electrode 180 may include at least one of, for example, metals such as doped polysilicon, ruthenium (Ru), titanium (Ti), tantalum (Ta), and tungsten (W); and metal nitrides, such as titanium nitride (TiN), tantalum nitride (TaN), tungsten nitride (WN), chromium nitride (CrN), vanadium nitride (VN), molybdenum nitride (MoN), niobium nitride (NbN), titanium silicon nitride (TiSiN), titanium aluminum nitride (TiAIN), and tantalum aluminum nitride (TaAIN). In one or more embodiments, each of the first electrode 160 and the second electrode 180 may include a single-layer structure or a multi-layer structure of the above material.

The dielectric layer structure 170 may include a first dielectric layer 171, a second dielectric layer 172, and a third dielectric layer 173. The first dielectric layer 171, the second dielectric layer 172, and the third dielectric layer 173 may be sequentially stacked on the first electrode 160. The first dielectric layer 171 may be the lowermost layer among stacked layers constituting the dielectric layer structure 170. The third dielectric layer 173 may be the uppermost layer among the stacked layers constituting the dielectric layer structure 170. For example, the first dielectric layer 171, which is lowermost, may face or contact the first electrode 160, and the third dielectric layer 173, which is uppermost, may face or contact the second electrode 180. However, the stacked layers of the dielectric layer structure 170 are not limited thereto.

For example, the third dielectric layer 173 may be stacked on the first dielectric layer 171, and the second dielectric layer 172 may be stacked on the third dielectric layer 173. In addition, the dielectric layer structure 170 may include a plurality of first dielectric layers 171, a plurality of second dielectric layers 172, and a plurality of third dielectric layers 173, and the plurality of first dielectric layers 171, the plurality of second dielectric layers 172, and the plurality of third dielectric layers 173 may be arranged in any order.

In one or more embodiments, the first dielectric layer 171 and the second dielectric layer 172 may include a ferroelectric material. For example, the first dielectric layer 171 and the second dielectric layer 172 may include at least one of HfO₂, Hf₁₋ₓZrₓO₂ (0<x≤0.5), Ba₁₋ₓSrₓTiO₃ (0≤x≤0.3), BaTiO₃, and PbZrₓTi₁₋ₓO₃ (0≤x<0.1). The first dielectric layer 171 and the second dielectric layer 172 may include different ferroelectric materials. The first dielectric layer 171 and the second dielectric layer 172 may include the same ferroelectric material.

In one or more embodiments, the first dielectric layer 171 and the second dielectric layer 172 may include a ferroelectric material and may be formed in different crystal phases. For example, the first dielectric layer 171 may be formed in a rhombohedral crystal phase. Additionally, the second dielectric layer 172 may be formed in an orthorhombic crystal phase.

In one or more embodiments, the third dielectric layer 173 may include an anti-ferroelectric material. For example, the third dielectric layer 173 may include at least one of ZrO₂, PbZrO₃, PbTiO₃, and AgNbO₃. Additionally, the third dielectric layer 173 may be formed in a tetragonal crystal phase. In addition, the third dielectric layer 173 may further include a paraelectric material in a monoclinic crystal phase or a cubic crystal phase.

The first dielectric layer 171 in a rhombohedral crystal phase may be formed by an atomic layer deposition (ALD) process. The first dielectric layer 171 may include a metal oxide and a metal dopant. The metal dopant may be dispersed within the metal oxide. The metal dopant may include metal atoms different from the metal oxide. A composition ratio of the metal dopant to the first dielectric layer 171 may be about 30% or less.

The metal oxide may include at least one of HfO₂, Hf₁₋ₓZrₓO₂ (0<x<0.5), Ba₁₋ₓSrₓTiO₃ (0≤x≤0.3), BaTiO₃, and PbZrₓTi₁₋ₓO₃ (0<x≤0.1). The metal dopant may include at least one of lanthanum (La), Ta, manganese (Mn), vanadium (V), niobium (Nb), strontium (Sr), barium (Ba), calcium (Ca), yttrium (Y), scandium (Sc), chromium (Cr), hafnium (Hf), zirconium (Zr), cobalt (Co), Ti, nickel (Ni), Si, aluminum (Al), and beryllium (Be).

The first dielectric layer 171 may be formed by implanting the metal dopant into the metal oxide. For example, the first dielectric layer 171 may be formed by implanting the metal dopant into the metal oxide in an interstitial form, but is not limited thereto. The first dielectric layer 171 may be formed by implanting the metal dopant into the metal oxide in a substitutional form.

In one or more embodiments, a metal oxide precursor in the ALD process for forming the first dielectric layer 171 may be different from a metal dopant precursor. The metal oxide precursor may be a material having an ALD window of about 350° C. or less. For example, the metal oxide precursor may include a material containing a cyclopentadienyl ligand, but is not limited thereto.

In one or more embodiments, the metal dopant precursor may be a material having an ALD window of about 200° C. to about 300° C. For example, the metal dopant precursor may include a material containing an amin ligand, but is not limited thereto. Therefore, the metal dopant precursor may undergo a chemical vapor deposition (CVD) reaction at the ALD window (about 350° C. or less) of the metal oxide precursor.

In one or more embodiments, the radius of a central metal ion of the metal dopant precursor may be different in size from the radius of a central metal ion of the metal oxide precursor. For example, the radius of the central metal ion of the metal dopant precursor may be about 0.7 Å or more. The metal dopant precursor may include at least one of La, Ta, Mn, V, Nb, Sr, Ba, Ca, Y, Sc, Cr, Hf, Zr, and Co. For example, the radius of the central metal ion of the metal dopant precursor may be about 0.7 Å or less. The metal dopant precursor may include at least one of Ti, Ni, Si, Al, and Be.

In one or more embodiments, since the first dielectric layer 171 includes a metal dopant, the crystal phase thereof may change, compared to a ferroelectric material that does not include a metal dopant (e.g., a second dielectric layer) but includes the same material as the first dielectric layer 171. The crystal phase of the first dielectric layer 171 may be in a distorted state. For example, the first dielectric layer 171 may be formed in a rhombohedral crystal phase. The degree of lattice strain of the first dielectric layer 171 may range from about-5% to about 10%, compared to a ferroelectric material that does not contain a metal dopant. Additionally, the degree of volume change due to the lattice strain of the first dielectric layer 171 may range from about-20% to about 30%, compared to a ferroelectric material that does not contain a metal dopant.

Since the integrated circuit device 100 includes the first dielectric layer 171 of which the crystal phase is distorted into a rhombohedral crystal phase, the characteristics of the integrated circuit device 100 may be improved. The first dielectric layer 171 in a rhombohedral crystal phase may have improved ferroelectric characteristics, compared to a conventional dielectric layer having only an orthorhombic crystal phase. For example, a coercive field (Ec) may be lowered and remnant polarization (Pr) may be increased. In addition, by increasing a dielectric constant of the capacitor structure CS, the capacitance of the capacitor structure CS may be increased. In addition, as the dielectric layer structure 170 includes the first dielectric layer 171 and a dielectric layer (e.g., dielectric layers 172 and 173) having different dielectric properties and/or crystal phases from the first dielectric layer 171, the dielectric properties of the dielectric layer structure 170 may be adjusted as needed.

In one or more embodiments, the second dielectric layer 172 may further include a metal dopant. For example, the second dielectric layer 172 may include, as a metal dopant, at least one of Al, Ti, Ta, Nb, La, Y, magnesium (Mg), Si, Ca, cerium (Ce), dysprosium (Dy), erbium (Er), gadolinium (Gd), Ge, Sc, Sr, and tin (Sn).

In one or more embodiments, the third dielectric layer 173 may further include a metal dopant. For example, the third dielectric layer 173 may include, as a metal dopant, at least one of Al, Ti, Nb, La, Y, Mg, Si, Ca, Ce, Dy, Er, Gd, Ge, Sc, Sr, and Sn.

In one or more embodiments, a first proportion of a ferroelectric material in the dielectric layer structure 170 may be less than a second proportion of an anti-ferroelectric material in the dielectric layer structure 170. For example, the first proportion of the ferroelectric material may be about 40% or less and the second proportion of the anti-ferroelectric material may be about 60% or more. The first proportion may refer to a proportion of the first dielectric layer 171 and the second dielectric layer 172 in the dielectric layer structure 170. The second proportion may refer to a proportion of the third dielectric layer 173 in the dielectric layer structure 170. A ratio of the first dielectric layer 171 to the second dielectric layer 172 in the first proportion may be designed in various ways as needed. By adjusting the first proportion and the second proportion, the dielectric properties of the dielectric layer structure 170 may be adjusted. For example, as the first proportion increases, the ferroelectric characteristics of the dielectric layer structure 170 may increase. Alternatively, the first proportion may refer to a proportion of ferroelectric material in the entire dielectric layer structure 170, and the second proportion may refer to a proportion of anti-ferroelectric material in the entire dielectric layer structure 170. That is, the first proportion and second proportion may not be limited to particular proportions per dielectric layer within the dielectric structure 170.

In one or more embodiments, the thickness of the dielectric layer structure 170 in a vertical direction (Z direction) with respect to the top surface of the first electrode 160 may be about 100 Å or less. The thickness of the first dielectric layer 171 in the vertical direction (Z direction) may be about 1 Å to about 50 Å. The thickness of the second dielectric layer 172 in the vertical direction (Z direction) may be about 1 Å to about 50 Å. The thickness of the third dielectric layer 173 in the vertical direction (Z direction) may be about 1 Å to about 50 Å.

FIGS. 2B-2D are enlarged views of a portion of an integrated circuit device according to one or more example embodiments.

The components that form integrated circuit devices to be described in FIGS. 2B-2D and the materials of the components may be the same or similar to those previously described with reference to FIGS. 1 and 2A. Therefore, for convenience of explanation, the description is made below focusing on the differences from the dielectric layer structure 170 of the integrated circuit device 100 described above, and repeated descriptions may be omitted.

FIG. 2B shows an enlarged portion CX11 of an integrated circuit device that is similar to the integrated circuit device of FIG. 1. Referring to FIG. 2B, a dielectric layer structure 270 may include a structure in which a plurality of first dielectric layers 271 and one second dielectric layer 272 are alternately stacked. The first dielectric layers 271 may be lowest and uppermost layers among stacked layers constituting the dielectric layer structure 270. For example, the lowermost first dielectric layer 271 may face or contact the first electrode 160, and the uppermost first dielectric layer 271 may face or contact the second electrode 180, but the structure is not limited thereto. The dielectric layer structure 270 may include a structure in which a plurality of second dielectric layers 272 and one first dielectric layer 271 are alternately stacked.

In one or more embodiments, the first dielectric layer 271 may include a ferroelectric material. For example, the first dielectric layer 271 may include at least one of HfO₂, Hf₁₋ₓZrₓO₂ (0<x≤0.5), Ba₁₋ₓSrₓTiO₃ (0≤x≤0.3), BaTiO₃, and PbZrₓTi₁₋ₓO₃ (0≤x≤0.1). The first dielectric layer 271 may be formed in a rhombohedral crystal phase.

The first dielectric layer 271 in a rhombohedral crystal phase may be formed by an ALD process. The first dielectric layer 271 may include a metal oxide and a metal dopant. The metal dopant may be dispersed within the metal oxide. The metal dopant may contain metal atoms different from the metal oxide. A composition ratio of the metal dopant to the first dielectric layer 271 may be about 30% or less.

In one or more embodiments, the second dielectric layer 272 may include an anti-ferroelectric material. For example, the second dielectric layer 272 may include at least one of ZrO₂, PbZrO₃, PbTiO₃, and AgNbO₃. The second dielectric layer 272 may be formed in a tetragonal crystal phase. That is, the dielectric layer structure 270 may include a combination of a ferroelectric material in a rhombohedral crystal phase and an anti-ferroelectric material in a tetragonal crystal phase.

In one or more embodiments, the second dielectric layer 272 may include a ferroelectric material. For example, the second dielectric layer 272 may include at least one of HfO₂, Hf₁₋ₓZrₓO₂ (0<x≤0.5), Ba₁₋ₓSrₓTiO₃ (0≤x≤0.3), BaTiO₃, and PbZrₓTi₁₋ₓO₃ (0≤x≤0.1). The second dielectric layer 272 may include a ferroelectric material in a crystal phase different from the first dielectric layer 271. The second dielectric layer 272 may be formed in an orthorhombic crystal phase. That is, the dielectric layer structure 270 may include a combination of a ferroelectric material in a rhombohedral crystal phase and a ferroelectric material in an orthorhombic crystal phase.

FIG. 2C shows an enlarged portion CX12 of an integrated circuit device that is similar to the integrated circuit device of FIG. 1. Referring to FIG. 2C, a dielectric layer structure 370 may include a structure in which a first dielectric layer 371 and a second dielectric layer 372 are stacked. In FIG. 2C, one first dielectric layer 371 and one second dielectric layer 372 are shown, but the structure is not limited thereto. A plurality of first dielectric layers 371 and a plurality of second dielectric layers 372 may be alternately stacked.

In one or more embodiments, the first dielectric layer 371 may include a ferroelectric material. For example, the first dielectric layer 371 may include at least one of HfO₂, Hf₁₋ₓZrₓO₂ (0<x≤0.5), Ba₁₋ₓSrₓ TiO₃ (0≤x≤0.3), BaTiO₃, and PbZrₓ Ti₁₋ₓO₃ (0≤x≤0.1). The first dielectric layer 371 may be formed in a rhombohedral crystal phase.

The first dielectric layer 371 in a rhombohedral crystal phase may be formed by an ALD process. The first dielectric layer 371 may include a metal oxide and a metal dopant. The metal dopant may be dispersed within the metal oxide. The metal dopant may contain metal atoms different from the metal oxide. A composition ratio of the metal dopant to the first dielectric layer 371 may be 30% or less.

In one or more embodiments, the second dielectric layer 372 may include an anti-ferroelectric material. For example, the second dielectric layer 372 may include at least one of ZrO₂, PbZrO₃, PbTiO₃, and AgNbO₃. The second dielectric layer 372 may be formed in a tetragonal crystal phase. That is, the dielectric layer structure 370 may include a combination of a ferroelectric material in a rhombohedral crystal phase and an anti-ferroelectric material in a tetragonal crystal phase.

In one or more embodiments, the second dielectric layer 372 may include a ferroelectric material. For example, the second dielectric layer 372 may include at least one of HfO₂, Hf₁₋ₓZrₓO₂ (0<x≤0.5), Ba₁₋ₓSrₓTiO₃ (0≤x<0.3), BaTiO₃, and PbZrₓ Ti₁₋ₓO₃ (0≤x≤0.1). The second dielectric layer 372 may include a ferroelectric material in a crystal phase different from the first dielectric layer 371. The second dielectric layer 372 may be formed in an orthorhombic crystal phase. That is, the dielectric layer structure 370 may include a combination of a ferroelectric material in a rhombohedral crystal phase and a ferroelectric material in an orthorhombic crystal phase.

FIG. 2D shows an enlarged portion CX13 of an integrated circuit device that is similar to the integrated circuit device of FIG. 1. Referring to FIG. 2D, a dielectric layer structure 470 may be formed as a single layer. The dielectric layer structure 470 formed as a single layer may include a first ferroelectric material in a rhombohedral crystal phase. Additionally, the dielectric layer structure 470 may include a second ferroelectric material in an orthorhombic crystal phase, an anti-ferroelectric material in a tetragonal crystal phase, or a combination thereof. The properties of the first ferroelectric material in a rhombohedral crystal phase, the second ferroelectric material in an orthorhombic crystal phase, and the anti-ferroelectric material in a tetragonal crystal phase may be substantially the same as those described with reference to FIGS. 1 to 2C.

In one or more embodiments, a first proportion of a ferroelectric material in the dielectric layer structure 470 may be less than a second proportion of an anti-ferroelectric material in the dielectric layer structure 470. For example, the first proportion may be about 40% or less and the second proportion may be about 60% or more. The first proportion may refer to a proportion of the first ferroelectric material and the second ferroelectric material in the dielectric layer structure 470. The second proportion may refer to a proportion of the anti-ferroelectric material in the dielectric layer structure 470. A ratio of the first ferroelectric material to the second ferroelectric material in the first proportion may be designed in various ways as needed. In FIG. 2D, as well as in one or more other embodiments, the first proportion may also refer to a proportion of ferroelectric material in the dielectric layer structure 470, and the second proportion may refer to a proportion of anti-ferroelectric material in the dielectric layer structure 470. That is, the first proportion may be a proportion without reference to an amount of the first ferroelectric material and an amount of the second ferroelectric material.

In one or more embodiments, the thickness of the dielectric layer structure 470 in a vertical direction (Z direction) with respect to the top surface of the first electrode 160 may be about 100 Å or less.

A dielectric layer structure is not limited to the dielectric layer structures 170, 270, 370, and 470 described with reference to FIGS. 1 to 2D and may be modified in various ways. The dielectric layer structure may include a ferroelectric material in a rhombohedral crystal phase, and may be designed in various ways to include an anti-ferroelectric material, a ferroelectric material, a paraelectric material, or a combination thereof. Additionally, if necessary, the dielectric layer structure may be designed to include four or more dielectric layers.

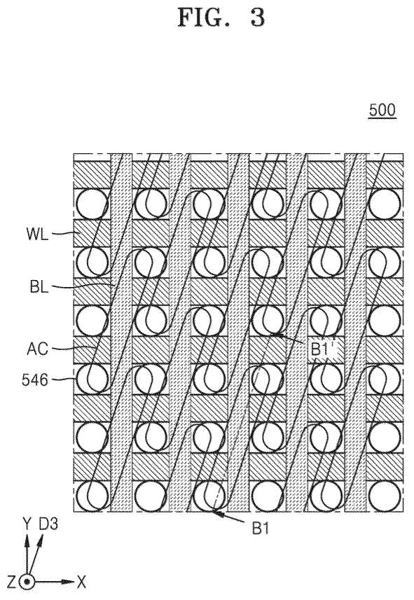

FIG. 3 is a diagram of an integrated circuit device according to one or more example embodiments.

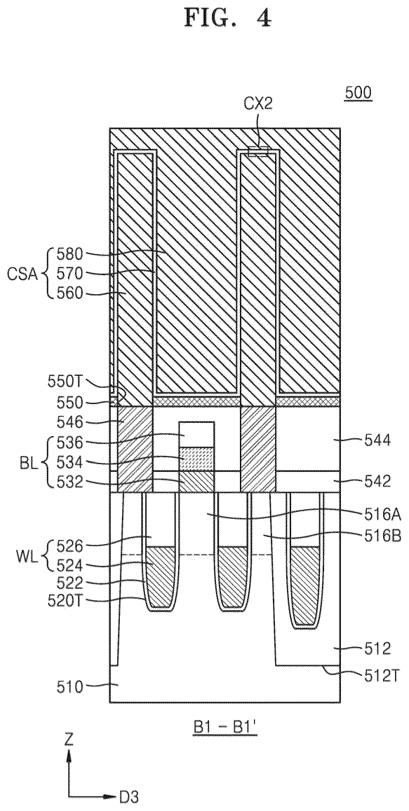

FIG. 4 is a cross-sectional view taken along line B1-B1′ in FIG. 3 according to one or more example embodiments.

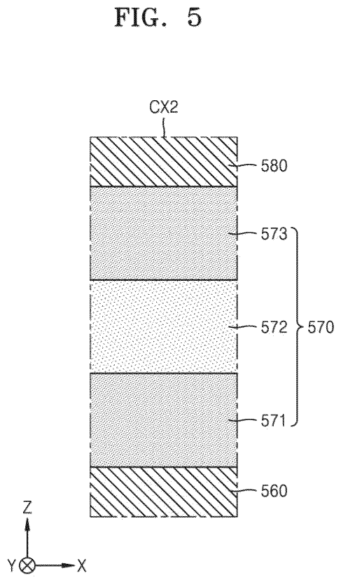

FIG. 5 is an enlarged view of portion CX2 in FIG. 4 according to one or more example embodiments.

Referring to FIGS. 3 to 5, an integrated circuit device 500 may include a capacitor structure CSA on a buried channel array transistor (BCAT) structure. The BCAT structure may include a gate insulating layer 522, a gate electrode 524, a gate capping layer 526, a bit line BL, and a contact structure 546. The bit line BL may include a bit line contact 532, a bit line conductive layer 534, and a bit line capping layer 536.

A substrate 510 may have an active area AC defined by a device isolation film 512. In one or more embodiments, the substrate 510 may be a Si wafer.

In one or more embodiments, the device isolation film 512 may have a shallow trench isolation (STI) structure. For example, the device isolation film 512 may include an insulating material that fills a device isolation trench 512T formed in the substrate 510. The insulating material may include fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), or tonen silazene (TOSZ), but is not limited thereto.

The active area AC may have a relatively long, island shape with a short axis and a long axis. As shown, the long axis of the active area AC may be arranged in a D3 direction parallel to the top surface of the substrate 510. In one or more embodiments, the active area AC may be of a first conductivity type. The first conductivity type may be p-type (or n-type).

The substrate 510 may be provided with a word line trench 520T extending in an X direction. The word line trench 520T may intersect with the active area AC and may be formed at a preset depth from the top surface of the substrate 510. A portion of the word line trench 520T may extend into the device isolation film 512, and a portion of the word line trench 520T formed in the device isolation film 512 may have a bottom surface at a lower level than a portion of the word line trench 520T formed in the active area AC.

A first source/drain region 516A and a second source/drain region 516B may be located on both sides of the word line trench 520T in the upper portion of the active region AC. The first source/drain region 516A and the second source/drain region 516B may be impurity regions doped with impurities of a second conductivity type that is different from the first conductivity type. The second conductivity type may be n-type (or p-type).

A word line WL may be formed inside the word line trench 520T. The word line WL may include a gate insulating layer 522, a gate electrode 524, and a gate capping layer 526, which are sequentially formed on the inner wall of the word line trench 520T.

The gate insulating layer 522 may be conformally formed on the inner wall of the word line trench 520T to a preset thickness. The gate insulating layer 522 may include at least one selected from silicon oxide, silicon nitride, silicon oxynitride, oxide/nitride/oxide (ONO), and a high-k dielectric having a higher dielectric constant than silicon oxide. For example, the gate insulating layer 522 may have a dielectric constant of about 10 to about 25. In one or more embodiments, the gate insulating layer 522 may include HfO₂, Al₂O₃, HfAlO₃, Ta₂O₃, TiO₂, or a combination thereof, but is not limited thereto.

The gate electrode 524 in the gate insulating layer 522 may fill the word line trench 520T from the bottom of the word line trench 520T to a predetermined height. The gate electrode 524 may include a work function control layer on the gate insulating layer 522 and a buried metal layer filling the bottom portion of the word line trench 520T on the work function control layer. For example, the work function control layer may include a metal, such as Ti, TIN, TiAIN, TIAIC, TiAICN, TiSiCN, Ta, TaN, TaAIN, TaAICN, TaSiCN, a metal nitride, or a metal carbide, and the buried metal layer may include at least one of W, WN, TiN, and TaN.

The gate capping layer 526 may fill the remaining portion of the word line trench 520T in the gate electrode 524. For example, the gate capping layer 526 may include at least one of silicon oxide, silicon oxynitride, and silicon nitride.

A bit line BL extending in a Y direction perpendicular to the X direction may be formed on the first source/drain region 516A. The bit line BL may include a bit line contact 532, a bit line conductive layer 534, and a bit line capping layer 536, which may be sequentially stacked on the substrate 510. For example, the bit line contact 532 may include polysilicon, and the bit line conductive layer 534 may include a metal material. The bit line capping layer 536 may include an insulating material, such as silicon nitride or silicon oxynitride. The bottom surface of the bit line contact 532 is shown to be at the same level as the top surface of the substrate 510. However, the bottom surface of the bit line contact 532 may also be formed at a lower level than the top surface of the substrate 510.

Alternatively, a bit line intermediate layer may be positioned between the bit line contact 532 and the bit line conductive layer 534. The bit line intermediate layer may include metal silicide, such as tungsten silicide, or metal nitride, such as tungsten nitride. A bit line spacer may be further formed on the sidewall of the bit line BL. The bit line spacer may include a single-layer structure or a multi-layer structure including an insulating material, such as silicon oxide, silicon oxynitride, or silicon nitride. Additionally, the bit line spacer may further include an air space.

A first interlayer insulating film 542 may be formed on the substrate 510, and the bit line contact 532 may penetrate the first interlayer insulating film 542 and may be connected to the first source/drain region 516A. The bit line conductive layer 534 and the bit line capping layer 536 may be disposed on the first interlayer insulating film 542. A second interlayer insulating film 544 on the first interlayer insulating film 542 may cover side surfaces of the bit line conductive layer 534, as well as side surfaces and the top surface of the bit line capping layer 536.

A contact structure 546 may be disposed on the second source/drain region 516B. The sidewalls of the contact structure 546 may be surrounded by the first interlayer insulating film 542 and the second interlayer insulating film 544. In one or more embodiments, the contact structure 546 may include a lower contact pattern, a metal silicide layer, and an upper contact pattern, which are sequentially stacked on the substrate 510, and a barrier layer surrounding the side and bottom surfaces of the upper contact pattern. In one or more embodiments, the lower contact pattern may include polysilicon and the upper contact pattern may include a metal material. The barrier layer may include a conductive metal nitride.

The capacitor structure CSA may be formed on the second interlayer insulating film 544. The capacitor structure CSA may include a lower electrode 560 electrically connected to the contact structure 546, a dielectric layer structure 570 on the lower electrode 560, and an upper electrode 580 on the dielectric layer structure 570. The dielectric layer structure 570 may include dielectric layer 571, dielectric layer 572 and dielectric layer 573. An etch stop film 550 having an opening 550T may be formed on the second interlayer insulating film 544, and the bottom of the lower electrode 560 may be formed within the opening 550T of the etch stop film 550.

The capacitor structures CSA are shown as being repeatedly arranged in the X direction on the contact structures 546 that are repeatedly arranged in the X direction. However, the capacitor structures CSA may be arranged in a hexagonal shape, such as a honeycomb structure, on the contact structures 546 that are repeatedly arranged in the X direction and the Y direction. In this case, a landing pad may be formed between the contact structure 546 and the capacitor structure CSA.

The lower electrode 560 may be formed in a pillar shape extending in the Z direction on the contact structure 546, and the dielectric layer structure 570 may be formed conformally on the top surface and sidewalls of the lower electrode 560. The upper electrode 580 may be disposed on the dielectric layer structure 570.

The lower electrode 560, the dielectric layer structure 570, and the upper electrode 580 may be substantially and respectively the same as the first electrode 160, the dielectric layer structures 170, 270, 370, and 470, and the second electrode 180, which are described with reference to FIGS. 1 to 2D. Therefore, repeated description thereof may be omitted.

The characteristics of the integrated circuit device 500 may be improved because the dielectric layer structure 570 includes a dielectric layer, such as dielectric layers 571, of which the crystal phase is distorted into a rhombohedral crystal phase. The dielectric layer in a rhombohedral crystal phase may have improved ferroelectric properties, compared to a dielectric layer having only a conventional orthorhombic crystal phase. In addition, by increasing a dielectric constant of the capacitor structure CSA, the capacitance of the capacitor structure CSA may be increased. Additionally, the dielectric properties of the dielectric layer structure 570 may be adjusted as needed through the design of the stacked structure of the dielectric layer structure 570.

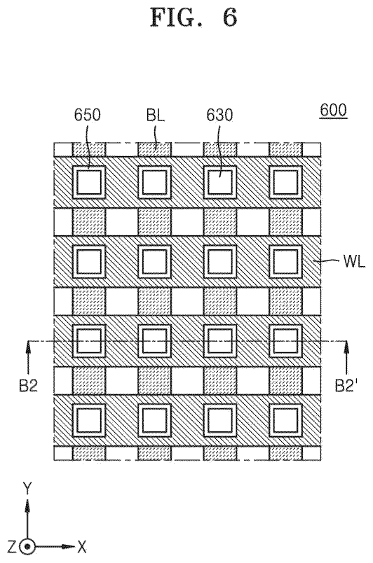

FIG. 6 is a diagram of an integrated circuit device according to one or more example embodiments.

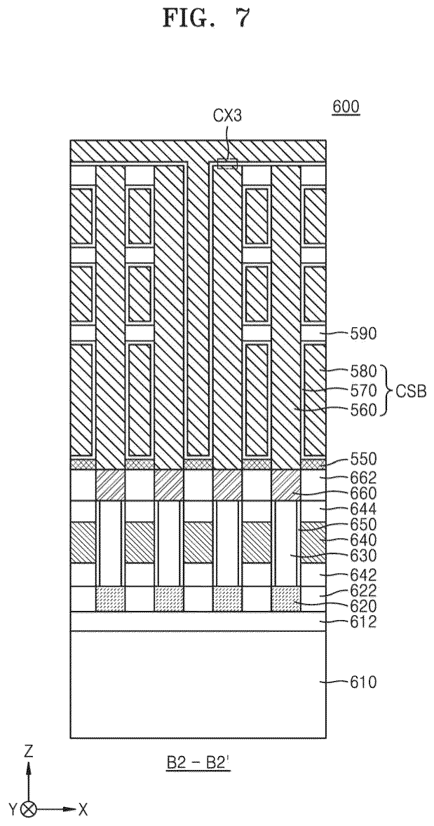

FIG. 7 is a cross-sectional view taken along line B2-B2′ in FIG. 6 according to one or more example embodiments.

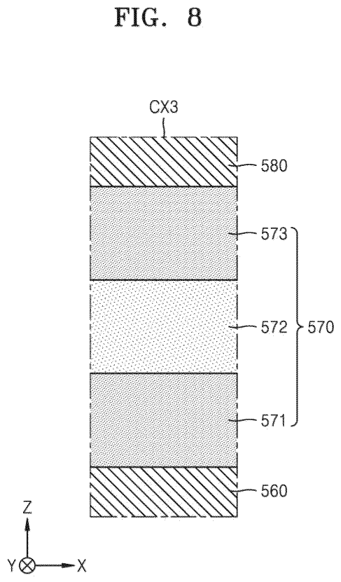

FIG. 8 is an enlarged view of portion CX3 in FIG. 7 according to one or more example embodiments.

Referring to FIGS. 6 to 8, an integrated circuit device 600 may include a capacitor structure CSB on a vertical channel transistor (VCT) structure. The VCT structure may include a first conductive lines 620, a channel layer 630, a gate electrode 640, a gate insulating layer 650, and a capacitor contact 660.

A lower insulating layer 612 may be disposed on a substrate 610, and a plurality of first conductive lines 620 on the lower insulating layer 612 may be spaced apart from each other in the X direction and extend in the Y direction. A plurality of first insulating patterns 622 on the lower insulating layer 612 may be arranged to fill the spaces between the plurality of first conductive lines 620. The plurality of first conductive lines 620 may correspond to bit lines BL of the integrated circuit device 600.

In one or more embodiments, the plurality of first conductive lines 620 may include doped polysilicon, metal, conductive metal nitride, conductive metal silicide, conductive metal oxide, or a combination thereof. For example, the plurality of first conductive lines 620 may include doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrO, RuO, or a combination thereof, but are not limited thereto. The plurality of first conductive lines 620 may include a single-layer structure or a multi-layer structure of the above materials. In one or more embodiments, the plurality of first conductive lines 620 may include a two-dimensional semiconductor material. For example, the two-dimensional semiconductor material may include graphene, carbon nanotubes, or a combination thereof.

Channel layers 630 may be arranged in island shapes spaced apart from each other in the X direction and the Y direction on the plurality of first conductive lines 620. The channel layers 630 may have a channel width in the X direction and a channel height in the Z direction, and the channel height may be greater than the channel width. A bottom portion of the channel layer 630 may function as a first source/drain region, an upper portion of the channel layer 630 may function as a second source/drain region, and a portion of the channel layer 630 between the first source/drain region and the second source/drain region may function as a channel region. The VCT structure may refer to a structure in which the channel length of the channel layer 630 extends from the substrate 610 in the Z direction.

In one or more embodiments, the channel layer 630 may include an oxide semiconductor. For example, the oxide semiconductor may include InxGayZnzO, InxGaySizO, InxSnyZnzO, InxZnyO, ZnxO, ZnxSnyO, ZnxOyN, ZrₓZnySnzO, SnxO, HfxInyZnzO, GaxZnySnzO, AlxZnySnzO, YbxGayZnzO, InxGayO, or a combination thereof. The channel layer 630 may include a single-layer structure or a multi-layer structure of the oxide semiconductor. In one or more embodiments, the channel layer 630 may have a bandgap energy that is greater than that of silicon. The channel layer 630 may be polycrystalline or amorphous, but is not limited thereto. In one or more embodiments, the channel layer 630 may include a two-dimensional semiconductor material including, for example, graphene, carbon nanotubes, or a combination thereof.

In one or more embodiments, gate electrodes 640 may surround sidewalls of the channel layers 630 and may extend in the X direction. The gate electrode 640 may be a gate-all-around type gate electrode that surrounds the entire sidewall of the channel layer 630. The gate electrode 640 may correspond to a word line WL of the integrated circuit device 600.

In one or more embodiments, the gate electrode 640 may be a dual gate type gate electrode and may include, for example, a first sub-gate electrode facing a first sidewall of the channel layer 630 and a second sub-gate electrode facing a second sidewall opposite to the first sidewall of the channel layer 630.

In one or more embodiments, the gate electrode 640 may be a single gate type gate electrode that covers only the first sidewall of the channel layer 630 and extends in the X direction.

The gate electrode 640 may include doped polysilicon, metal, conductive metal nitride, conductive metal silicide, conductive metal oxide, or a combination thereof. For example, the gate electrode 640 may include doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOx, or a combination thereof, but is not limited thereto.

A gate insulating layer 650 may surround a sidewall of the channel layer 630 and may be positioned between the channel layer 630 and the gate electrode 640. In one or more embodiments, the gate insulating layer 650 may include a silicon oxide film, a silicon oxynitride film, a high-k dielectric film having a higher dielectric constant than the silicon oxide film, or a combination thereof. The high-k dielectric film may include metal oxide or metal oxynitride. For example, the high-k dielectric film constituting the gate insulating layer 650 may include HfO₂, HfSiO, HfSiON, HfTaO, HfTIO, HfZrO, ZrO₂, Al₂O₃, or a combination thereof, but is not limited thereto.

First buried insulating layers 642 surrounding lower sidewalls of the channel layers 630 may be disposed on the plurality of first insulating patterns 622, and second buried insulating layers 644 surrounding upper sidewalls of the channel layers 630 and covering the gate electrodes 640 may be disposed on the first buried insulating layers 642.

Capacitor contacts 660 may be disposed on the channel layers 630. The capacitor contacts 660 may be arranged to vertically overlap with the channel layer 630 and may be arranged in a matrix form in which the capacitor contacts 660 are spaced apart from each other in the X direction and the Y direction. For example, the capacitor contacts 660 may include doped polysilicon, Al, Cu, Ti, Ta, Ru, W, Mo, Pt, Ni, Co, TiN, TaN, WN, NbN, TiAl, TiAIN, TiSi, TiSiN, TaSi, TaSIN, RuTiN, NiSi, CoSi, IrO, RuO, or a combination thereof, but is not limited thereto. Upper insulating layers 662 on the second buried insulating layers 644 may surround sidewalls of the capacitor contacts 660.

The etch stop film 550 may be disposed on the upper insulating layer 662, and the capacitor structure CSB may be disposed on the etch stop film 550. The capacitor structure CSB may include a lower electrode 560, a dielectric layer structure 570, and an upper electrode 580. The dielectric layer structure 570 may include dielectric layers 571 and 572. The lower electrode 560 may be electrically connected to the capacitor contact 660, the dielectric layer structure 570 may cover the lower electrode 560, and the upper electrode 580 on the dielectric layer structure 570 may cover the lower electrode 560. Support members 590 may be disposed on the sidewall of the lower electrode 560.

The lower electrode 560, the dielectric layer structure 570, and the upper electrode 580 may be substantially and respectively the same as the first electrode 160, the dielectric layer structures 170, 270, 370, and 470, and the second electrode 180, which are described with reference to FIGS. 1 to 2D. Therefore, repeated description thereof may be omitted.

The characteristics of the integrated circuit device 600 may be improved because the dielectric layer structure 570 includes a dielectric layer, such as dielectric layers 571, of which the crystal phase is distorted into a rhombohedral crystal phase. The dielectric layer in a rhombohedral crystal phase may have improved ferroelectric properties, compared to a dielectric layer having only a conventional orthorhombic crystal phase. In addition, by increasing a dielectric constant of the capacitor structure CS, the capacitance of the capacitor structure CSA may be increased. Additionally, the dielectric properties of the dielectric layer structure 570 may be adjusted as needed through the design of the stacked structure of the dielectric layer structure 570.

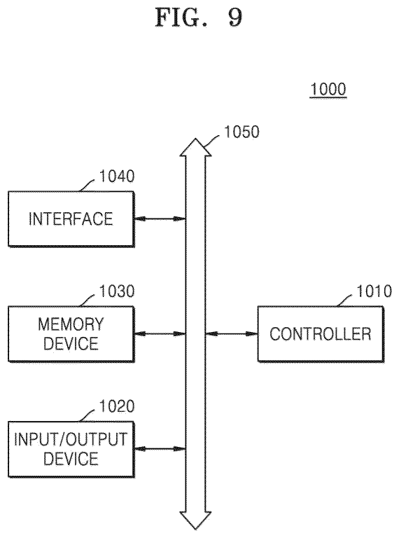

FIG. 9 is a diagram of a system including an integrated circuit device according to one or more example embodiments.

Referring to FIG. 9, a system 1000 may include a controller 1010, an input/output device 1020, a memory device 1030, an interface 1040, and a bus 1050.

The system 1000 may be a mobile system or a system that transmits or receives information. In one or more embodiments, the mobile system may include a portable computer, a web tablet, a mobile phone, a digital music player, or a memory card.

The controller 1010 for controlling an execution program in the system 1000 may include a microprocessor, a digital signal processor, a microcontroller, or a similar device.

The input/output device 1020 may be used to input or output data of the system 1000. The system 1000 may be connected to an external device, for example, a personal computer or a network, using the input/output device 1020 and may exchange data with the external device. The input/output device 1020 may include, for example, a touch screen, a touch pad, a keyboard, or a display.

The memory device 1030 may store data for the operation of the controller 1010 or may store data processed by the controller 1010. The memory device 1030 may include any one of the integrated circuit devices 100, 500, and 600 described above.

The interface 1040 may be a data transmission path between the system 1000 and an external device. The controller 1010, the input/output device 1020, the memory device 1030, and the interface 1040 may communicate with each other via the bus 1050.

At least one of the devices, units, components, modules, units, or the like represented by a block or an equivalent indication in the above embodiments including, but not limited to, FIG. 9, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An integrated circuit device comprising:
a transistor on a substrate; and
a capacitor structure connected to the transistor,
wherein the capacitor structure comprises:
a first electrode;
a dielectric layer structure on the first electrode and in which a plurality of dielectric layers are stacked; and
a second electrode on the dielectric layer structure, and
wherein the plurality of dielectric layers comprise:
a first dielectric layer comprising a ferroelectric material in a rhombohedral crystal phase; and
a second dielectric layer in a crystal phase different from the rhombohedral crystal phase of the first dielectric layer.

2. The integrated circuit device of claim 1, wherein the second dielectric layer comprises a ferroelectric material in an orthorhombic crystal phase.

3. The integrated circuit device of claim 1, wherein the second dielectric layer comprises an anti-ferroelectric material in a tetragonal crystal phase.

4. The integrated circuit device of claim 3, wherein the second dielectric layer further comprises a paradielectric material in a monoclinic crystal phase or a cubic crystal phase.

5. The integrated circuit device of claim 1, wherein a first proportion of the first dielectric layer in the dielectric layer structure is less than a second proportion of the second dielectric layer in the dielectric layer structure.

6. The integrated circuit device of claim 5, wherein the first proportion is 40% or less, and
wherein the second proportion is 60% or more.

7. The integrated circuit device of claim 1, wherein the first dielectric layer comprises a metal oxide and a metal dopant in the metal oxide.

8. The integrated circuit device of claim 7, wherein a first radius of a central metal ion in the metal oxide is different from a second radius of a central metal ion in the metal dopant.

9. The integrated circuit device of claim 8, wherein the second radius of the central metal ion in the metal dopant is about 0.7 Å or more.

10. The integrated circuit device of claim 1, wherein a thickness of the first dielectric layer in a vertical direction with respect to a top surface of the first electrode is about 1 Å to about 50 Å, and
wherein a thickness of the second dielectric layer in the vertical direction is about 1 Å to about 50 Å.

11. An integrated circuit device comprising:
a transistor on a substrate; and
a capacitor structure connected to the transistor,
wherein the capacitor structure comprises:
a first electrode;
a dielectric layer structure on the first electrode; and
a second electrode on the dielectric layer structure,
wherein the dielectric layer structure comprises a single layer, and
wherein the dielectric layer structure comprises a first ferroelectric material in a rhombohedral crystal phase.

12. The integrated circuit device of claim 11, wherein the dielectric layer structure further comprises a second ferroelectric material in an orthorhombic crystal phase, an anti-ferroelectric material in a tetragonal crystal phase, or a combination thereof.

13. The integrated circuit device of claim 11, wherein the dielectric layer structure further comprises a combination of a second ferroelectric material in an orthorhombic crystal phase and an anti-ferroelectric material in a tetragonal crystal phase, and
wherein a first proportion of the first ferroelectric material and the second ferroelectric material in the dielectric layer structure is less than a second proportion of the anti-ferroelectric material in the dielectric layer structure.

14. The integrated circuit device of claim 13, wherein the first proportion is 40% or less, and
wherein the second proportion is 60% or more.

15. The integrated circuit device of claim 11, wherein a thickness of the dielectric layer structure in a vertical direction with respect to a top surface of the first electrode is about 100 Å or less.

16. The integrated circuit device of claim 11, wherein the first ferroelectric material further comprises a metal oxide comprising hafnium (Hf) and a metal dopant in the metal oxide.

17. An integrated circuit device comprising:
a transistor on a substrate; and
a capacitor structure connected to the transistor,
wherein the capacitor structure comprises:
a first electrode;
a dielectric layer structure on the first electrode and in which a plurality of dielectric layers are stacked; and
a second electrode on the dielectric layer structure,
wherein the plurality of dielectric layers comprise:
a first dielectric layer comprising a first ferroelectric material in a rhombohedral crystal phase;
a second dielectric layer comprising a second ferroelectric material in an orthorhombic crystal phase; and
a third dielectric layer comprising an anti-ferroelectric material in a tetragonal crystal phase.

18. The integrated circuit device of claim 17, wherein a first proportion of ferroelectric material in the dielectric layer structure is 40% or less, and
wherein a second proportion of the anti-ferroelectric material in the dielectric layer structure is 60% or more.

19. The integrated circuit device of claim 17, wherein the third dielectric layer further comprises a paradielectric material in a monoclinic crystal phase or a cubic crystal phase.

20. The integrated circuit device of claim 17, wherein the first ferroelectric material further comprises a metal oxide comprising hafnium (Hf) and a metal dopant in the metal oxide.
